(19) United States
(12) Patent Application Publication
(10) Pub. No.: US 2012/0273931 A1
(43) Pub. Date: Nov. 1, 2012

(54) Integrated circuit chip package and manufacturing method thereof

(75) Inventors: Hsi-Chen Yang, Taichung City (TW); Ya-Tzu Wu, Bade City (TW)

(73) Assignee: Richtek Technology Corporation, R.O.C.

(21) Appl. No.: 13/200,161

(22) Filed: Sep. 20, 2011

(30) Foreign Application Priority Data
Apr. 26, 2011 (TW) 100114457

(51) Int. Cl. H01L 23/495; H01L 21/50

(52) U.S. Cl. 257/676; 438/123; 438/108; 257/E23.033; 257/E21.499

(57) ABSTRACT

The present invention discloses an integrated circuit (IC) chip package and a manufacturing method thereof. The IC chip package includes: a lead frame, including a lead frame array having plural conductive cells, wherein some of the conductive cells are respectively electrically connected with corresponding first extended wires; at least one redistribution layer, wherein each redistribution layer includes plural second extended wires, which are respectively electrically connected to the first extended wires or the second extended wires of another redistribution layer; and a solder array, including plural solder balls, which are electrically connected to the lead frame array.

### CROSS REFERENCE

The present invention claims priority to TW 100114457, filed on Apr. 26, 2011.

### BACKGROUND OF THE INVENTION

1. Field of Invention

The present invention relates to an integrated circuit (IC) chip package and a manufacturing method of packaging the IC chip.

2. Description of Related Art

FIGS. 1A and 1B show schematic diagrams of a top view and a cross-section view of a lead frame package, respectively. Referring to FIG. 1A, a lead frame 10 includes multiple leads 1. The leads 1 are electrically connected to an IC chip 2 via multiple wires 3 by wire-bonding. FIG. 1B shows a cross-section view along the cross-section line AA′ in FIG. 1A. Referring to FIG. 1B, the IC chip 2 is attached to a die paddle of the lead frame 10, and then it is electrically connected to the leads 1 of the lead frame 10 by wire-bonding. Next, a molding layer 4 encapsulates and molds the IC chip 2, the lead frame 10, and wires 3 to complete the IC chip package. By fixing the leads 1 to the circuit board 6, the IC chip 2 becomes part of the circuit board 6.

As recent technology development requires shrinking the size of the IC chip package, the pitch between leads in the lead frame 10 needs to be reduced. However, in the aforementioned prior art, the pitch between the leads in the lead frame 10 can be reduced only to a certain limit; the IC chip package can not be shrunk below a minimum size, and thus the manufacturing cost (and the consumption of the wires 3 as well) cannot be reduced.

In view of the foregoing, the present invention provides an IC chip package and a manufacturing method of packaging the IC chip, wherein the size of the IC chip package is effectively reduced, so as to reduce the consumption of the wires and to reduce the manufacturing cost of the IC chip package.

### SUMMARY OF THE INVENTION

The objectives of the present invention are to provide an IC chip package and a manufacturing method of packaging the IC chip.

To achieve the objectives mentioned above, from one perspective, the present invention provides an IC chip package for packaging an IC chip, comprising: a lead frame, including a lead frame array having plural conductive cells, wherein some of the conductive cells are respectively electrically connected with corresponding first extended wires; at least one redistribution layer, wherein each redistribution layer includes plural second extended wires, which are respectively electrically connected to the first extended wires or the second extended wires of another redistribution layer; and a solder array, including plural solder balls, which are electrically connected to the lead frame array.

From another perspective, the present invention provides a manufacturing method of packaging an IC chip, comprising: providing a lead frame, which includes a lead frame array having plural conductive cells, wherein some of the conductive cells are respectively electrically connected with corresponding first extended wires; forming at least one redistribution layer, wherein each redistribution layer includes plural second extended wires, which are respectively electrically connected to the first extended wires or the second extended wires of another redistribution layer; and electrically connecting a solder array including plural solder balls to the lead frame array.

In a preferred embodiment, the IC chip package further comprises a metal bond pads array, including multiple metal bond pads, which are electrically connected to the lead frame array; and an encapsulation layer for encapsulating the metal bond pads array, wherein the encapsulation layer includes a solder mask.

The objectives, technical details, features, and effects of the present invention will be better understood with regard to the detailed description of the embodiments below.

### BRIEF DESCRIPTION OF THE DRAWINGS

FIG. 1A shows a schematic diagram of a top view of a conventional lead frame package.

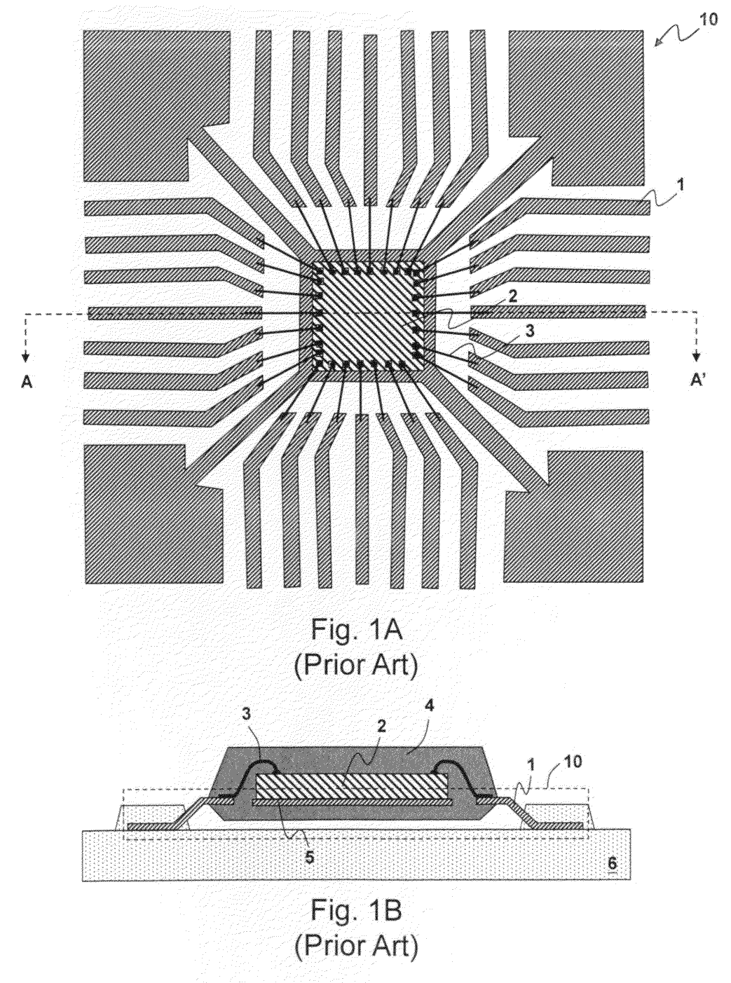

FIG. 1B shows a schematic diagram of a cross-section view of a conventional lead frame package.

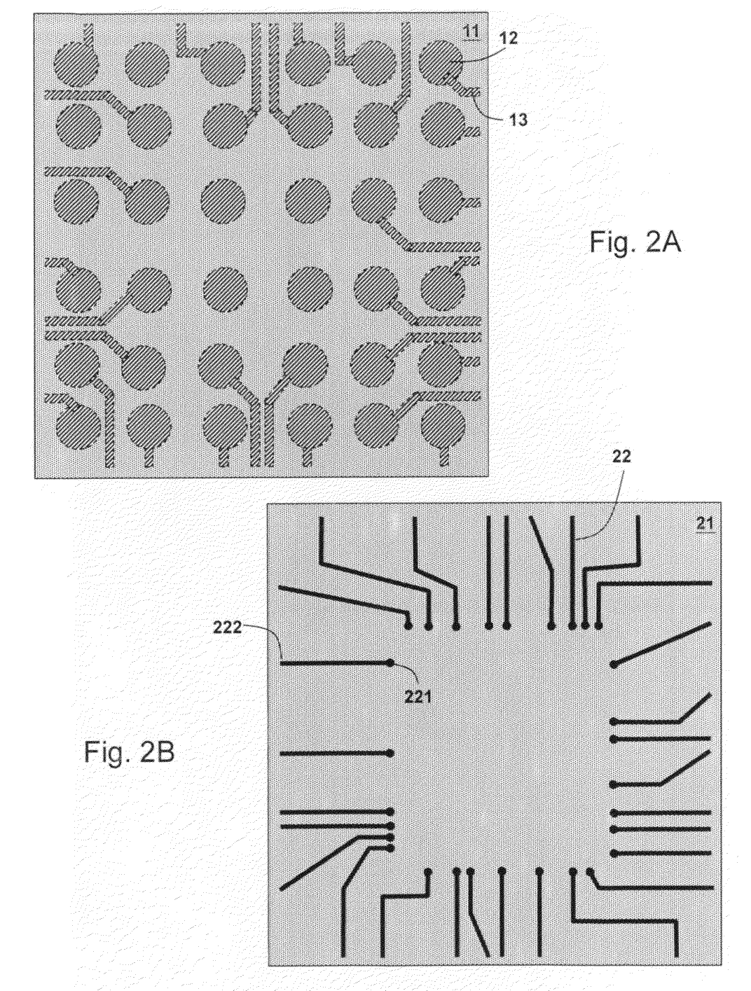

FIGS. 2A-2F show a first embodiment of the present invention.

FIG. 3 shows another embodiment of the present invention.

FIG. 4 shows yet another embodiment of the present invention.

### DESCRIPTION OF THE PREFERRED EMBODIMENTS

The drawings as referred to throughout the description of the present invention are for illustration only, but not drawn according to actual scale.

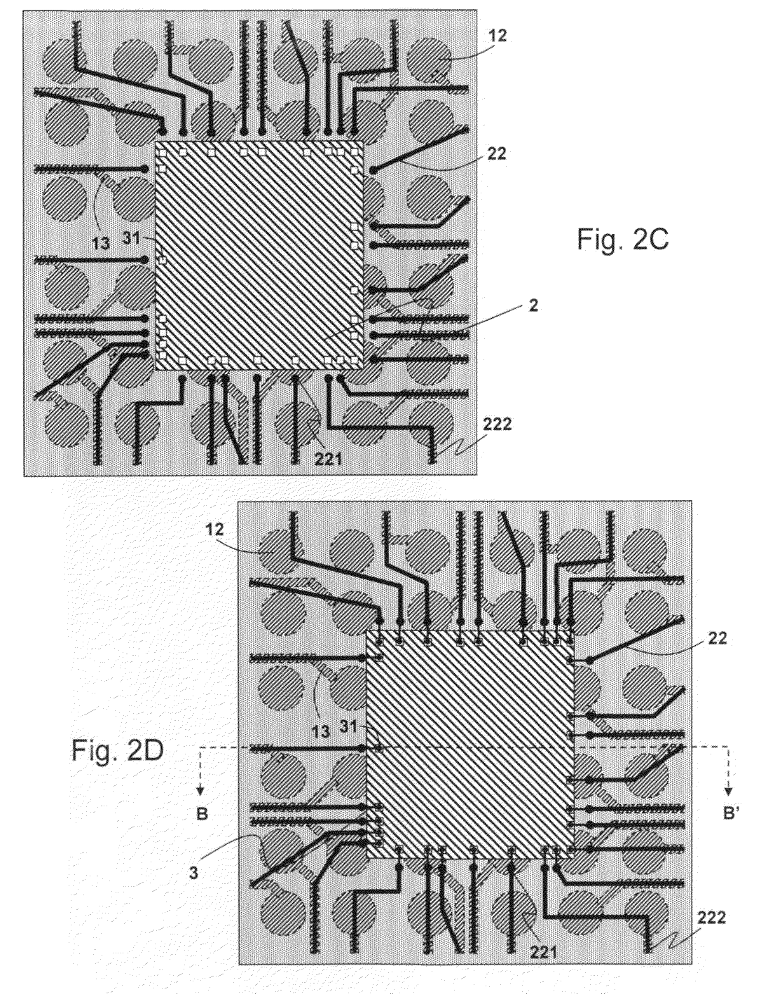

Please refer to FIGS. 2A-2F, which show a first embodiment of the present invention. As shown in FIG. 2A, a lead frame 11 includes a lead frame array which has plural conductive cells 12, wherein some of the conductive cells 12 are respectively electrically connected with corresponding first extended wires 13. The shape of the conductive cell 12 is shown for example as a circle in the figure, but alternatively the shape can be a square, or any other arbitrary shape. In the layout shown in FIG. 2A, all the far ends of the first extended wires 13 are extended to the edge of the lead frame 11; this is just shown for example but not for limiting the present invention, and the layout of the first extended wires 13 may be otherwise arranged such as locating the far ends of the first extended wires 13 at other proper locations, as long as the layout of the first extended wires 13 match with (i.e., can be properly electrically connected to) the layout of a redistribution layer to be formed above the lead frame 11.

Next, as shown in FIG. 2B, a redistribution layer 21 includes plural second extended wires 22 is formed, wherein each of the second extended wire 22 has a first end 221 and a second end 222. In this embodiment, the second ends 222 are used to be electrically connected to the corresponding ends of the first extended wires 13 of the lead frame 11 respectively. According to the present invention, there may be one or more redistribution layers 21. However, in order to simplify the figure for easier understanding of the relationship between upper and lower layers, only one single redistribution layer 21 is used in this embodiment. In another embodiment wherein multiple redistribution layers 21 are provided, the layout of the second extended wires 22 may be arbitrarily arranged as long as the second extended wires 22 of different redistribution layers 21 can be properly electrically connected with one another, or properly electrically connected to the first extended wires 13 of the lead frame 11, to provide desired electrical connection for the conductive cells 12.

In the next, referring to FIG. 2C, after the redistribution layer 21 is formed on the lead frame 11 and the redistribution layer 21 is electrically connected to the lead frame 11, an IC chip 2 is placed on the redistribution layer 21, wherein the IC chip 2 has multiple chip bond pads 31, which are electrically connected to the first ends 221 of the second extended wires 22. From top view, the second ends 222 of the second extended wires 22 are overlapped with the far ends of the first extended wires 13, respectively. The layout of the wires is for easier and better electrical connections, which will be described later by embodiments. The first ends 221 of the second extended wires 22 are preferably located around the IC chip 2 for easier and better electrical connections to the chip bond pads 31.

Further next, referring to FIG. 2D, the chip bond pads 31 are electrically connected to the corresponding first ends 221 of the second extended wires 22 by wire-bonding with wires 13, or by flip-chip connection with bumps 53. FIG. 2E shows a cross-section view along the cross-section line BB′ in FIG. 2D. The IC chip 2 is attached to the distribution layer 21, and after the wire-bonding process, the IC chip 2 is electrically connected to the first ends 221 of the second extended wires 22 of the distribution layer 21. FIG. 2F shows a cross-section view along the cross-section line BB′ in FIG. 2D. The IC chip 2 is electrically connected to the first ends 221 of the second extended wires 22 of the distribution layer 21 by a flip-chip connection process. Then, a molding layer 4 encapsulates the redistribution layer 21 and the IC chip 2. The second ends 222 of the extended wires 22 are electrically connected to the ends of the first extended wires 13 of the lead frame 11 respectively via connection plugs 52 of a connection layer 51. Thereafter, multiple solder balls 42 of a solder array 41 are electrically connected to the conductive cells 12 respectively, to complete the IC chip package.

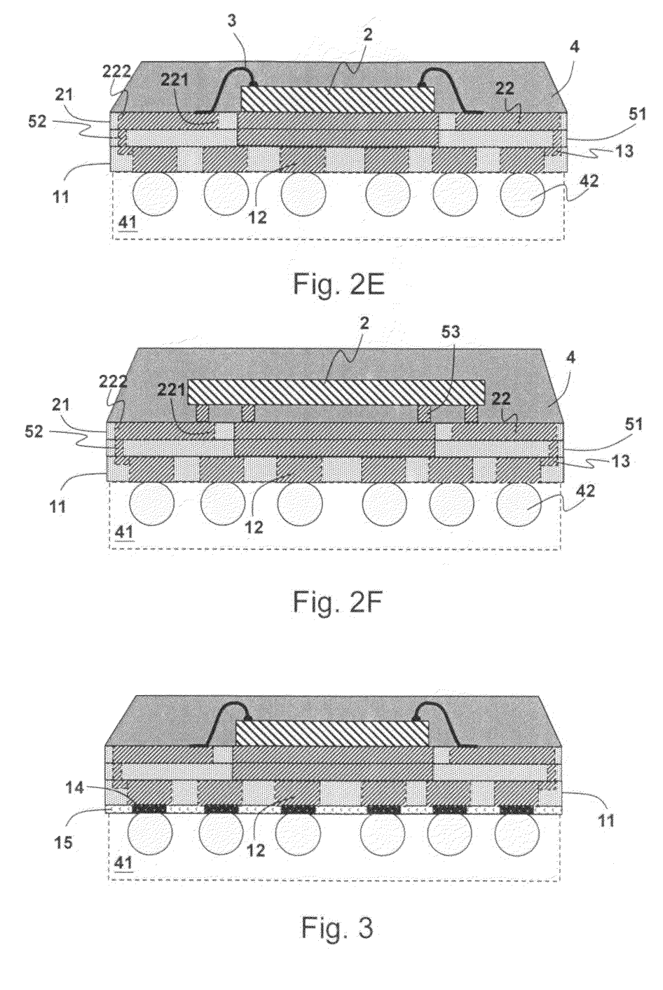

FIG. 3 shows another embodiment of the present invention. This embodiment is different from the first embodiment in that, the IC chip package of this embodiment further includes a metal bond pads array between the lead frame 11 and the solder array 41, and an encapsulation layer 15 for encapsulating the metal bond pads array. The metal bond pads array includes multiple metal bond pads 14, and the multiple metal bond pads 14 are electrically connected to the multiple conductive cells 12 of the lead frame array respectively. The encapsulation layer 15 for example may be, but not limited to, a solder mask.

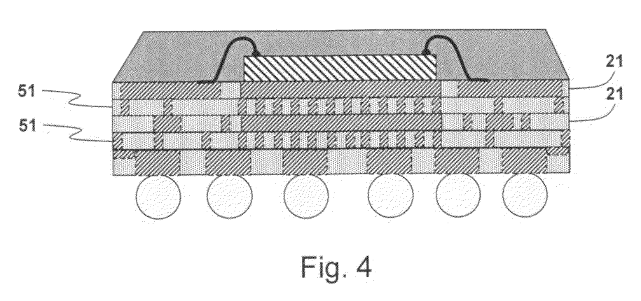

FIG. 4 shows yet another embodiment of the present invention. This embodiment is different from the first embodiment in that, this embodiment includes multiple redistribution layers 21. The multiple redistribution layers 21 are electrically connected to each other, the chip bond pads 31, and the first extended wires 13 by multiple connection layers 51.

The present invention reduces the length of the wires for wire-bonding by single or multiple redistribution layers, such that the manufacturing cost is reduced, and the layout arrangement becomes much easier because the difficulty in the prior art due to different lengths of the wires is solved. The present invention also reduces the pitch between leads, such that the size of the IC chip package can be reduced.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, the lead frame array, the solder array, or the metal bond pads array may be arranged in any other shape besides square. For another example, the chip bond pads may be located at other locations on the IC chip besides the edges. In view of the foregoing, the spirit of the present invention should cover all such and other modifications and variations, which should be interpreted to fall within the scope of the following claims and their equivalents.

What is claimed is:

1. An integrated circuit (IC) chip package for packaging an IC chip, comprising:
a lead frame, including a lead frame array having plural conductive cells, wherein some of the conductive cells are respectively electrically connected with corresponding first extended wires;
at least one redistribution layer, wherein each redistribution layer includes plural second extended wires, which are respectively electrically connected to the first extended wires or the second extended wires of another redistribution layer; and
a solder array, including plural solder balls, which are electrically connected to the lead frame array.

2. The IC chip package of claim 1, further comprising a molding layer for encapsulating the redistribution layer and the IC chip.

3. The IC chip package of claim 1, further comprising:
a metal bond pads array, including a plurality of metal bond pads, which are electrically connected to the lead frame array; and
an encapsulation layer for encapsulating the metal bond pads array.

4. The IC chip package of claim 3, wherein the encapsulation layer includes a solder mask.

5. The IC chip package of claim 1, wherein the IC chip includes a plurality of chip bond pads, which are electrically connected to the second extended wires by wire-bonding or flip-chip connection.

6. A manufacturing method of packaging an IC chip, comprising:
providing a lead frame, which includes a lead frame array having plural conductive cells, wherein some of the conductive cells are respectively electrically connected with corresponding first extended wires;
forming at least one redistribution layer, wherein each redistribution layer includes plural second extended wires, which are respectively electrically connected to the first extended wires or the second extended wires of another redistribution layer; and
electrically connecting a solder array including plural solder balls to the lead frame array.

7. The method of claim 6, further comprising encapsulating the redistribution layer and the IC chip with a molding layer.

8. The method of claim 6, further comprising:
providing a metal bond pads array, including a plurality of metal bond pads, which are electrically connected to the lead frame array; and
encapsulating the metal bond pads array with an encapsulation layer.

9. The method of claim 8, wherein the encapsulation layer includes a solder mask.

10. The method of claim 6, wherein the IC chip includes a plurality of chip bond pads, and the method further comprising electrically connecting the chip bond pads of the IC chip to the second extended wires by wire-bonding or flip-chip connection.
